(19) United States
(12) Patent Application Publication
(10) Pub. No.: US 2003/0178923 A1
(43) Pub. Date: Sep. 25, 2003

(54) Display device and manufacturing method of the same

(75) Inventors: Tetsuji Omura, Ogaki-shi (JP); Toru Sasatani, Motosu-gun (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-City (JP)

(21) Appl. No.: 10/377,116

(22) Filed: Mar. 3, 2003

(30) Foreign Application Priority Data
Mar. 4, 2002 (JP) 2002-057009

(51) Int. Cl. H01J 5/02

(52) U.S. Cl. 313/44; 313/317

(57) ABSTRACT

A coating start point is altered to avoid flowing of a sealing resin to an EL element when the sealing resin is pressed and flattened on adhesion of a device substrate and a sealing substrate with the sealing resin interposed therebetween. In a manufacturing method of a display device of the invention which is formed by adhering the device substrate and the sealing substrate with the sealing resin interposed therebetween, when the sealing resin is coated along edges of the device substrate and the sealing substrate, the coating is started on a corner of the substrates as a coating start point and a coating end point is on the same corner as for the coating start point.

### BACKGROUND OF THE INVENTION

1. Field of the Invention

This invention relates to a display device provided with a self-emission element, especially to a display device provided with an electroluminescenct element and a thin film transistor.

2. Description of the Related Art

In recent years, an electroluminescenct (hereafter, referred to as an EL) display device with an EL element is receiving an attention as a display device substituting for a CRT and an LCD. For example, research and developments are being pursued for the EL display device provided with a thin film transistor (hereafter, referred to as a TFT) as a switching device for driving the EL element.

The above-mentioned EL display device is formed, for example, by laminating the TFT and an organic EL element sequentially on a transparent glass substrate (hereafter, referred to as an insulating substrate).

A gate electrode is formed on the insulating substrate, and a gate insulating film and an active layer made of a p-Si film are laminated sequentially thereon.

In the active layer, a channel is provided above the gate electrode and source and drain regions are severally provided on both sides of the channel above the gate electrode.

An interlayer insulating film is formed on whole surfaces of the gate insulating film and the active layer, and a drain electrode is formed by filling metal such as Al in a contact hole provided correspondingly to the drain region.

Furthermore, on a whole surface of the interlayer insulating film, there are formed a planarization insulation layer for planarizing the surface, which is made of, for example, organic resin, and a contact hole on a position corresponding to the source region in the planarization insulation layer. On the planarization insulation layer, there is formed an anode of the EL device, which serves as a source electrode made of ITO (Indium Tin Oxide) and contacting to the source region through the contact hole.

A hole transport layer is formed on the anode of ITO and an emissive layer is formed thereon. An electron transport layer is formed to cover the emissive layer and a cathode is laminated thereon.

FIGS. 4A and 4B are explanatory views of a sealing procedure of a conventional EL display device. First, as shown in FIGS. 4A and 4B, a device substrate 200 and a sealing substrate 300 made of a glass substrate are adhered with a sealing resin 400 interposed therebetween, which is made of, for example, epoxy resin and coated on the sealing substrate 300 by a dispenser. The device substrate 200 and the sealing substrate 300 are adhered by heating and hardening the sealing resin interposed therebetween.

For coating the sealing resin 400 along edges of the sealing substrate 300 as shown in FIG. 5A, the coating starts at an almost middle point of an edge of the sealing substrate 300, which is referred to as a coating start point 411, then terminated at a coating end point, which is identical to the coating start point 411, and the sealing resin 400 is connected at a connect point 413. As shown in FIG. 5B, however, when pressing and planarization the sealing resin 400 with the sealing substrate 300 and the device substrate 200, the sealing resin 400 spreads and sometimes flows to the EL device, thereby causing poor operation of the EL device. The reference number 412 is a coating leading point during the coating.

Conventionally, to avoid the flow of the sealing resin to the EL device by the spread of the sealing resin, a margin is provided in a space between the EL device and the sealing resin. Therefore, there is a need to reduce a size of a display region or increase a size of a display device itself.

Furthermore, a method to avoid the flow of the sealing resin requires providing a groove on the sealing substrate and coating the sealing resin therein. In this method, however, a groove forming process is needed on the sealing substrate, thereby leading to increased cost.

### SUMMARY OF THE INVENTION

The invention provides a display device including a device substrate, a sealing substrate and a resin layer disposed on peripheral portions of the device and sealing substrates and attaching the sealing substrate to the device substrate. The resin layer includes a connect portion that is formed both as a start point and an end point of a resin layer formation. The connect portion is located at a corner of the sealing substrate and at a corner of the device substrate corresponding to the corner of the sealing substrate.

The invention also provides a manufacturing method of a display device. The method include providing a device substrate and providing a sealing substrate. The method also includes depositing a line of a sealing resin on peripheral portions of the device substrate. The line depositing of the sealing resin starts from one of the corner portions of the device substrate and ends at the same corner portion of the device substrate. The method further includes attaching the sealing substrate to the device substrate using the sealing resin as an adhesive.

The invention further includes a manufacturing method of a display device. The method includes providing a device substrate and providing a sealing substrate. The method also includes depositing a line of a sealing resin on peripheral portions of the sealing substrate. The line depositing of the sealing resin starts from one of the corner portions of the sealing substrate and ends at the same corner portion of the sealing substrate. The method further includes attaching the sealing substrate to the device substrate using the sealing resin as an adhesive.

The invention also provides a display device including a device substrate, a sealing substrate, and a resin layer disposed on peripheral portions of the device and sealing substrates and attaching the sealing substrate to the device substrate. The resin layer includes a connect portion that is formed both as a start point of a resin layer formation and an end point of another resin layer formation. The connect portion is located at a corner of the sealing substrate and at a corner of the device substrate corresponding to the corner of the sealing substrate.

The invention further provides a display device including a device substrate, a sealing substrate, and a resin layer disposed on peripheral portions of the device and sealing substrates and attaching the sealing substrate to the device substrate. The resin layer includes a connect portion that is wider than other portions of the resin layer. The connect portion is located at a corner of the sealing substrate and at a corner of the device substrate corresponding to the corner of the sealing substrate.

### BRIEF DESCRIPTION OF THE DRAWINGS

FIGS. 1A and 1B are explanatory views of a coating procedure with a sealing resin on a substrate of an embodiment of this invention, and FIG. 1C is an explanatory view of another coating procedure of this embodiment.

FIG. 2 is a plan view of an EL display device of the embodiment of this invention.

FIGS. 3A and 3B are cross-sectional views of the EL display device of FIG. 2.

FIGS. 4A and 4B are explanatory views of a conventional sealing between a device substrate and a sealing substrate.

FIGS. 5A and 5B are explanatory views of a conventional coating procedure with a sealing resin on a substrate.

### DETAILED DESCRIPTION OF THE INVENTION

An embodiment of this invention will be described as being applicable to an organic EL display device.

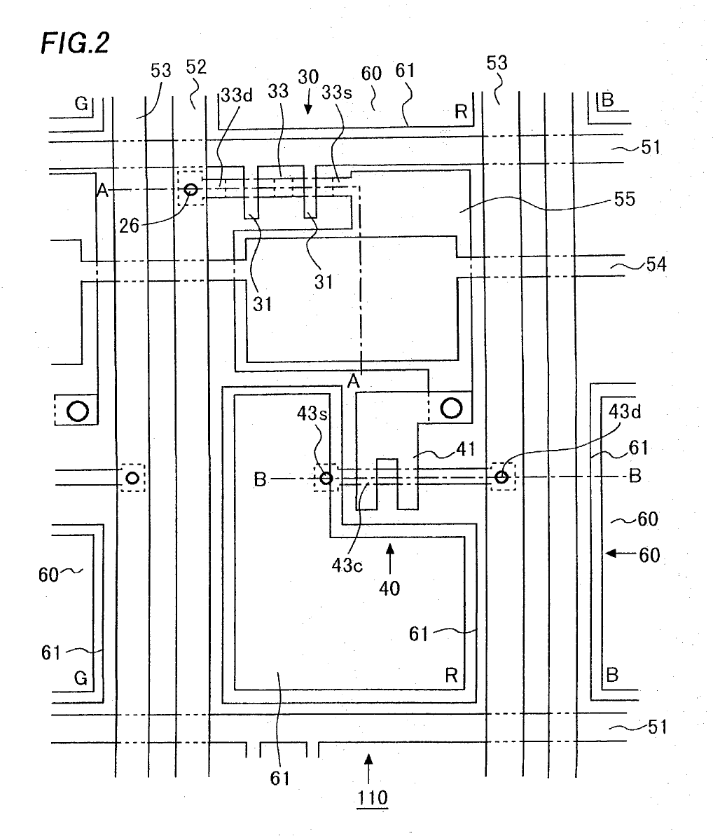

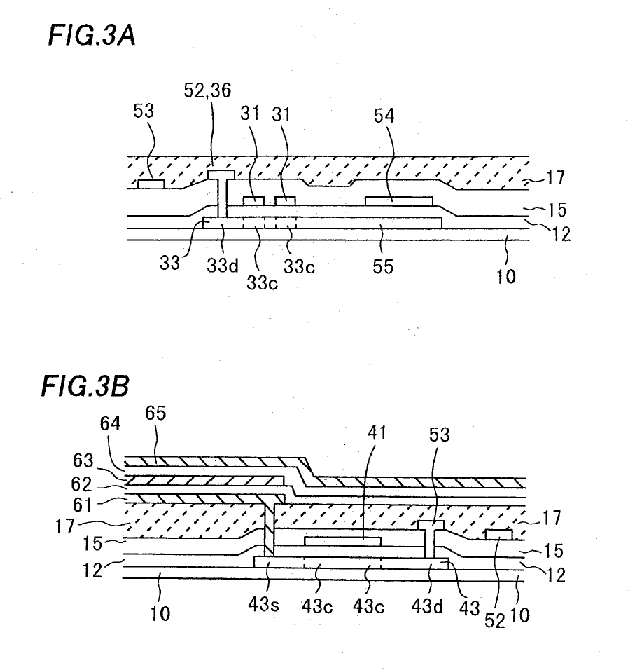

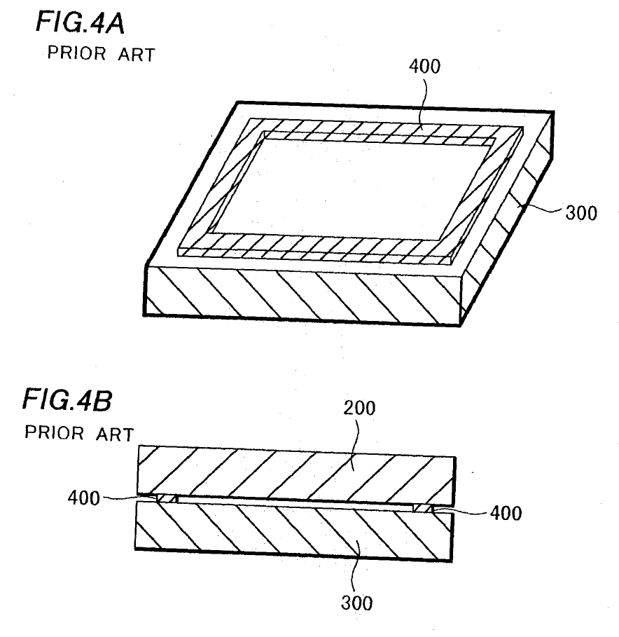

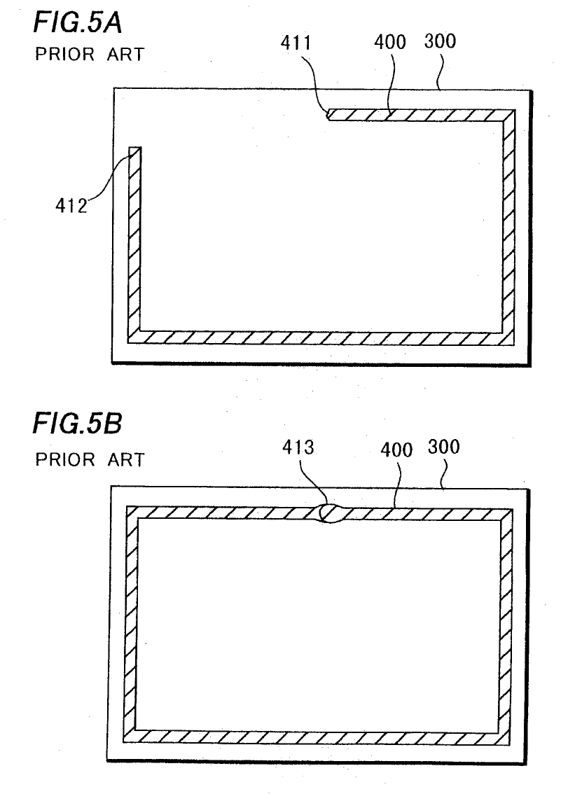

FIG. 2 shows a plane view of a pixel of the organic EL display device of this embodiment. FIG. 3A shows a sectional view along A-A line of FIG. 2 and FIG. 3B shows a sectional view along B-B line of FIG. 2.

As shown in FIG. 2, a pixel 110 is formed in a region enclosed with a gate signal line 51 and a drain signal line 52. The pixels 10 are disposed in a matrix.

There are disposed in the pixel 110 an organic EL element 60 as a self-emission device, a switching TFT 30 for controlling a timing of supplying an electric current to the organic EL element 60, a driving TFT 40 for supplying an electric current to the organic EL element 60 and a storage capacitor. The organic EL element 60 is formed of an anode 61, an emissive layer made of an emission material, and a cathode 65.

The switching TFT 30 is provided in a periphery of a point of intersection of the both signal lines 51 and 52. A source 33s of the switching TFT 30 serves as a capacitor electrode 55 for forming a capacitor with a storage capacitor electrode line 54 and is connected to a gate electrode 41 of the driving TFT 40. A source 43s of the driving TFT 40 is connected to the anode 61 of the organic EL element 60, while a drain 43d is connected to a driving source line 53 as a current source to be supplied to the organic EL element 60.

The storage capacitor electrode line 54 is disposed in parallel with the gate signal line 51. The storage capacitor electrode line 54 is made of Cr (chromium) and forms a capacitor by storing an electric charge with the capacitor electrode 55 connected to the source 33s of the TFT through a gate insulating film 12. A storage capacitor 56 is provided for storing voltage applied to the gate electrode 41 of the driving TFT 40.

As shown in FIGS. 3A and 3B, the organic EL display device is formed by laminating the TFTs and the organic EL element sequentially on a substrate 10 such as a substrate made of glass or synthetic resin, a conductive substrate, or a semiconductor substrate. When using a conductive substrate or a semiconductor substrate as the substrate 10, however, an insulating film such as SiO₂ or SiN is formed on the substrate 10, and then the switching TFT 30, the driving TFT 40 and the organic EL element 60 are formed thereon. Each of the both TFTs has a so-called top gate structure in which a gate electrode is disposed above an active layer with a gate insulating film being interposed therebetween.

There will be described the switching TFT 30 first.

As shown in FIG. 3A, an amorphous silicon film (hereafter, referred to as an a-Si film) is formed on the insulating substrate 10 made of a silica glass or a non-alkali glass by a CVD method. The a-Si film is irradiated by laser beams for melting and recrystalizing to form a poly-silicon film (hereafter, referred to as a p-Si film) as an active layer 33. On the active layer 33, a single-layer or a multi-layer of an SiO₂ film and an SiN film is formed as the gate insulating film 12. There are disposed on the gate insulating film 12 the gate signal line 51 made of metal having a high melting point such as Cr(chromium) or Mo(molybdenum) and also serving as a gate electrode 31, the drain signal line 52 made of Al(aluminum), and the driving source line 53 made of Al and serving as a driving source of the organic EL element.

An interlayer insulating film 15 laminated with an SiO₂ film, an SiN film and an SiO₂ film sequentially is formed on whole surfaces of the gate insulating film 12 and the active layer 33. There is provided a drain electrode 36 by filling metal such as Al in a contact hole provided correspondingly to a drain 33d. Furthermore, a planarization insulation film 17 for planarization a surface which is made of organic resin is formed on a whole surface.

Next, there will be described the driving TFT 40 of the organic EL element. As shown in FIG. 3B, an active layer 43 formed by poly-crystalizing an a-Si film by irradiating laser beams thereto, the gate insulating film 12, and the gate electrode 41 made of metal having a high melting point such as Cr or Mo are formed sequentially on the insulating substrate 10 made of a silica glass or a non-alkali glass. There are provided in the active layer 43 a channel 43c, and a source 43s and a drain 43d on both sides of the channel 43c. The interlayer insulating film 15 laminated with an SiO₂ film, an SiN film and an SiO₂ film sequentially is formed on whole surfaces of the gate insulating film 12 and the active layer 43. There is disposed the driving source line 53 connected to a driving source by filling metal such as Al in a contact hole provided correspondingly to a drain 43d. Furthermore, a planarization insulation film 17 for planarization a surface, which is made of, for example, organic resin etc is formed on a whole surface. A contact hole is formed in a position corresponding to a source 43s in the planarization insulation film 17. There is formed on the planarization insulation film 17 a transparent electrode made of ITO and contacting to the source 43s through the contact hole, i.e., the anode 61 of the organic EL element. The anode 61 is formed in each of the pixels, being isolated as an island.

The organic EL element 60 has a structure of laminating sequentially the anode 61 made of a transparent electrode such as ITO, a first hole transport layer made of MTDATA (4,4-bis (3-methylphenylphenylamino) biphenyl), a hole transport layer 62 made of a second hole transport layer made of TPD (4,4,4-tris (3-methylphenylphenylamino)triphenylanine), an emissive layer 63 made of Bebq₂ (bis (10-hydroxybenzo[h]quinolinato)beryllium) containing a quinacridone derivative, an electron transport layer 64 made of Bebq₂ and a cathode 65 made of a magnesium-indium alloy, aluminum or an aluminum alloy.

In the organic El element 60, a hole injected from the anode 61 and an electron injected from the cathode 65 are recombined in the emissive layer and an exciton is formed by exciting an organic module forming the emissive layer 63. Light is emitted from the emissive layer 63 in a process of relaxation of the exciton and then released outside after going through the transparent anode 61 to the transparent insulating substrate 10, thereby completing light-emission.

The substrate integrated with the above-mentioned EL element 60 is referred to as a device substrate 200 hereafter and there will be described a resin-sealing structure of the EL element 60 of the device substrate 200 with a sealing substrate 300 and a sealing resin 400.

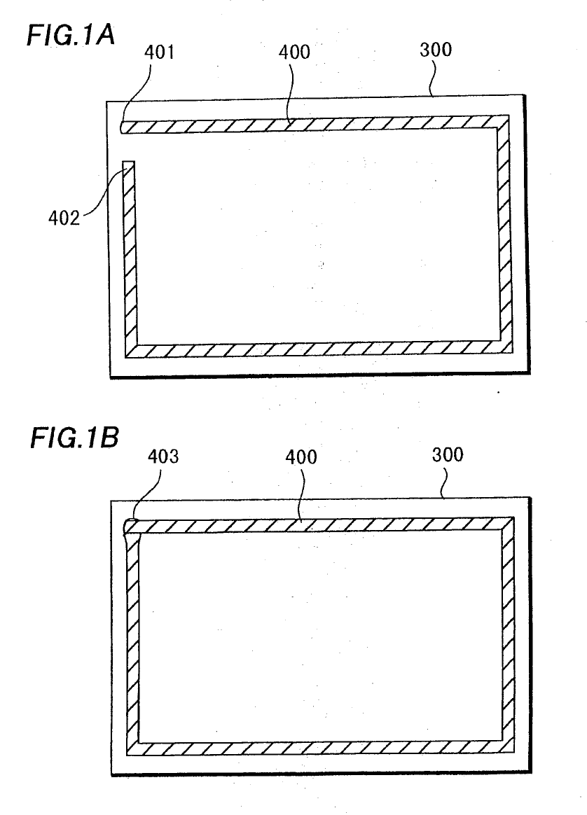

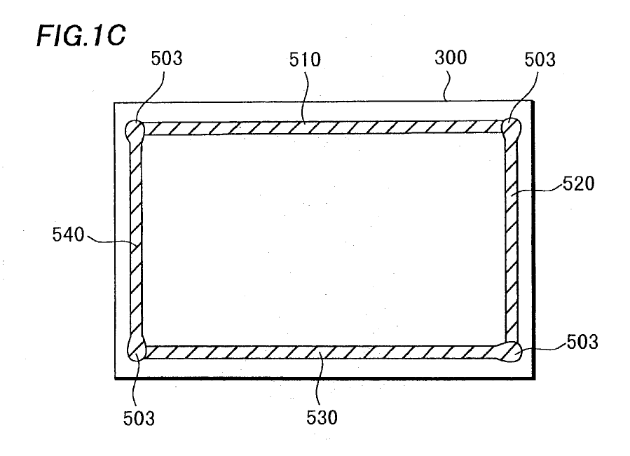

In this embodiment, as shown in FIGS. 1A and 1B, when the sealing resin is coated along edges of the device substrate 200 and the sealing substrate 300, a coating start point 401 for starting the coating of the sealing resin 400 on the sealing substrate 300 is on a corner of the sealing substrate 300. The sealing resin 400 is coated from the coating start point 401, and the sealing resin 400 is connected at a coating end point, which is identical to the coating start point 401. The reference number 402 is a coating leading point during the coating and 403 is a connect point formed at the end of the coating.

In the coating procedure of FIGS. 1A and 1B, one resin coating line 400 surrounds the central portion of the sealing substrate 300, in which the EL elements are sealed when the display device is completed. However, in other coating procedure, which is applicable to this embodiment, one resin coating line 510, 520, 530, 540 is formed for each edge of the sealing substrate 300, as shown in FIG. 1C. Accordingly, four connect points 503 are formed at four corners of the sealing substrate 300, respectively. For example, a connect point 503 is formed at the upper left corner where the horizontal resin coating line 510 and the vertical resin coating line 540 meet. Because of the overlapping of the two resin coating lines, the connect point 503 becomes wider than the rest of the resin coating line when the sealing substrate is pressed onto the device substrate 200 for the adhesion.

When the sealing substrate 300 is attached to the device substrate 200 using the resin coating lines, the device substrate itself may receive the similar resin coating layer for easy adhesion. Alternatively, the coating layer may be formed only on the device substrate 200 and the sealing substrate 300 without coating layer may be attached to the device substrate 200.

The corners of the device substrate 200 and the sealing substrate 300 have larger area available for coating manipulation than other portions of the edge regions (for example, a center of the edge of the substrate where the coating conventionally starts). In other words, on the corners, spacing between the sealing resin 400 and the EL element 60 is larger. Therefore, even if the sealing resin 400 is pressed and flattened to spread as shown in FIG. 1B, on adhesion of the device substrate 200 and the sealing substrate 300, flowing of the sealing resin 400 to the EL element 60 can be avoided.

Accordingly, in this embodiment, the method above prevents the flowing of the sealing resin 400 to the EL element 60 and poor operation of the EL element 60.

Furthermore, the embodiment of this invention is not limited to the EL display, and is also applicable to a variety of display devices such as a liquid crystal display.

According to this embodiment, when a sealing resin is coated on edges of a device substrate and a sealing substrate, a corner of the substrates is set as a coating start point, a coating end point is on the same corner as the coating start point, and the sealing resin is connected on the corner of the substrates. Even if the sealing resin at this point spreads wider than the sealing resin at other parts, the contact of the sealing resin to the EL element can be avoided since the corner is large enough to accommodate the spread of the sealing resin. Consequently, the sealing resin does not flow to the EL device, thereby preventing poor operation of the EL device.

What is claimed is:

1. A display device comprising:
a device substrate;
a sealing substrate; and
a resin layer disposed on peripheral portions of the device and sealing substrates and attaching the sealing substrate to the device substrate, the resin layer comprising a connect portion that is formed both as a start point and an end point of a resin layer formation,
wherein the connect portion is located at a corner of the sealing substrate and at a corner of the device substrate corresponding to said corner of the sealing substrate.

2. The display device of claim 1, wherein the connect portion of the resin layer is wider than the rest of the resin layer that is not the connect portion.

3. The display device of claim 1, wherein the device substrate includes an electroluminescent element.

4. The display device of claim 2, wherein the device substrate includes an electroluminescent element.

5. A manufacturing method of a display device, comprising:
providing a device substrate;
providing a sealing substrate;
depositing a line of a sealing resin on peripheral portions of the device substrate, the line depositing of the sealing resin starting from one of the corner portions of the device substrate and ending at said one of the corner portion of the device substrate; and
attaching the sealing substrate to the device substrate using the sealing resin as an adhesive.

6. The manufacturing method of a display device of claim 5, wherein the device substrate includes an electroluminescent element and the electroluminescent element is encircled by the line of the sealing resin.

7. A manufacturing method of a display device, comprising:
providing a device substrate;
providing a sealing substrate;
depositing a line of a sealing resin on peripheral portions of the sealing substrate, the line depositing of the sealing resin starting from one of the corner portions of the sealing substrate and ending at said one of the corner portion of the sealing substrate; and
attaching the sealing substrate to the device substrate using the sealing resin as an adhesive.

8. The manufacturing method of a display device of claim 7, wherein the device substrate includes an electroluminescent element and the electroluminescent element is encircled by the line of the sealing resin.

9. A display device comprising:
a device substrate;
a sealing substrate; and
a resin layer disposed on peripheral portions of the device and sealing substrates and attaching the sealing substrate to the device substrate, the resin layer comprising a connect portion that is formed both as a start point of a resin layer formation and an end point of another resin layer formation,
wherein the connect portion is located at a corner of the sealing substrate and at a corner of the device substrate corresponding to said corner of the sealing substrate.

10. A display device comprising:
a device substrate;
a sealing substrate; and
a resin layer disposed on peripheral portions of the device and sealing substrates and attaching the sealing substrate to the device substrate, the resin layer comprising a connect portion that is wider than other portions of the resin layer,
wherein the connect portion is located at a corner of the sealing substrate and at a corner of the device substrate corresponding to said corner of the sealing substrate.
